(19) United States
(12) Patent Application Publication
(10) Pub. No.: US 2025/0107019 A1
(43) Pub. Date: Mar. 27, 2025

(54) DISPLAY DEVICE

(71) Applicant: FANUC CORPORATION, Yamanashi (JP)

(72) Inventor: Junichi SAKAMOTO, Yamanashi (JP)

(73) Assignee: FANUC CORPORATION, Yamanashi (JP)

(21) Appl. No.: 18/729,753

(22) PCT Filed: Mar. 30, 2022
(86) PCT No.: PCT/JP2022/015995

§ 371 Date: Jul. 17, 2024

(51) Int. Cl. H05K 5/02

(52) U.S. Cl. CPC H05K 5/0217

(57) ABSTRACT

A display device according to the present disclosure comprises a display unit, a control unit that controls the display unit, and a connection part that connects the display unit and the control unit. The connection part can attach and detach the back surface side of the display unit and the control unit to and from each other. To the control unit, an external connector for connection with the outside thereof is connectable. In a state where the control unit is secured to the back surface side of the display unit, the mating/unmating direction of the external connector is a direction in which the back surface of the display unit extends, and the connection part rotatably connects the external connector in a state where the control unit is turnably disposed so as to move away from or toward the back surface side of the display unit and the external connector is disposed outside in a radial direction.

### TECHNICAL FIELD

The present invention relates to a display device provided on, for example, a machine tool, and particularly relates to a display device in which a display unit and a controller therefor are structurally independent of each other.

### BACKGROUND ART

Patent Document 1 discloses a display device including a display unit and a control unit. In the display device, the control unit, which is independent of the display unit, is detachably connected to the back surface of the display unit.

According to the known art, as depicted in FIG. 16, a display device 101 including a display unit 102 and a control unit 103 has connected thereto an external connector 118 for connecting to an external element. The external connector 118 can be inserted/removed into/from, in the thickness direction of a housing 105 in which the display device 101 is provided (typically, front-rear direction D1), a connector (not shown) provided at the lower edge portion of the control unit 103. Thus, the housing 105 has an increased thickness, thereby upsizing the display device 101.

A front-rear direction D1, an up-down direction D2, and a left-right direction D3 are defined in FIG. 16 with the display screen of the display unit 102 being viewed from the front. To be specific, the direction from the control unit 103 toward the display unit 102 is defined as a frontward direction D11, a direction opposite to the frontward direction D11 is defined as a rearward direction D12, and the frontward direction D11 and the rearward direction D12 are collectively defined as the front-rear direction D1. An upward direction D21 and a downward direction D22 opposite to the upward direction D21 are collectively defined as the up-down direction D2.

Accordingly, a proposition has been made to match the insertion/removal direction of an external connector with the direction in which the back surface of a display unit extends. Typically, the external connector is provided at the lower edge portion of a control unit such that the external connector can be inserted/removed in the up-down direction. In this way, the thickness of the housing is decreased so that the display device can be compact.

In this case, however, when an attempt is made, on the back side of the display unit, to insert/remove the external connector, it is difficult to see the insertion port through which the external connector is inserted into the control unit, thereby worsening the insertion/removal performance of the external connector. Furthermore, the insertion/removal space for the external connector is narrow, so the workability is low. In view of this, the external connector may be inserted/removed while the control unit, which has been removed from the display unit, is placed on a worktable.

When the display device has been provided in the housing, cables connected to the external connector are fixed by a clamp member or bundled by being inserted through a duct. Thus, the cables have almost no extra length, and, in many cases, the control unit removed from the display unit cannot be carried to the worktable.

### Citation List

### Patent Document

Patent Document 1: Japanese Unexamined Patent Application, Publication No. 2014-38130

### DISCLOSURE OF THE INVENTION

### Problems to be Solved by the Invention

As described above, the conventional display device has various problems. Accordingly, a display device is desired that has a compact configuration and into/from which an external connector for connecting to an external element can be easily inserted/removed in order to solve the problems.

### Means for Solving the Problems

One aspect of the present disclosure is a display device including a display unit, a control unit that controls the display unit, and a connection part that connects the display unit and the control unit. The connection part is capable of detachably connecting a back side of the display unit to the control unit; the control unit is capable of having connected thereto an external connector for connecting to an element external to the control unit. When the control unit has been fixed to the back side of the display unit, the insertion/removal direction of the external connector is the direction in which the back surface of the display unit extends. The connection part establishes a connection such that the control unit is capable of being turned so as to be spaced apart from or approach the back side of the display unit and such that the external connector is capable of being rotated with the external connector being disposed on the outside in the radial direction.

### Effects of the Invention

One aspect can provide a display device that has a compact configuration and into/from which an external connector for connecting to an external element can be easily inserted/removed.

### BRIEF DESCRIPTION OF THE DRAWINGS

FIG. 1 is a perspective view illustrating a usage state in a first embodiment of the display device of the present invention;

FIG. 2 is an exploded perspective view illustrating the display device according to the first embodiment of the present invention, with the display device being viewed from the back side;

FIG. 3 is a perspective view illustrating a display unit of the display device according to the first embodiment of the present invention, with the display unit being viewed from the back side;

FIG. 4 is a front view illustrating a control unit of the display device according to the first embodiment of the present invention;

FIG. 5 is a perspective view illustrating the control unit of the display device according to the first embodiment of the present invention, with the control unit being viewed from the foreside;

FIG. 6 is a perspective view illustrating a site where the display unit and the control unit are connected, with the cross section of a portion of the site being depicted;

FIG. 7 is a side view illustrating the usage state of the display device according to the first embodiment of the present invention, with the cross section of a portion of the display device being depicted, and with the control unit having been moved toward the back side with reference to the display unit;

FIG. 8 is a side view illustrating the usage state of the display device according to the first embodiment of the present invention, with the cross section of a portion of the display device being depicted, and with the control unit having been moved, in comparison with the state in FIG. 7, in a downward direction perpendicular to the movement direction in FIG. 7;

FIG. 9 is a perspective view illustrating the usage state of the display device according to the first embodiment of the present invention, with the control unit having been turned (inclined) in comparison with the state in FIG. 8;

FIG. 10 is a perspective view illustrating a display unit of a display device according to a second embodiment of the present invention, with the display unit being viewed from the back side;

FIG. 11 is a side view illustrating the usage state of the display device according to the second embodiment of the present invention, with the cross section of a portion of the display device being depicted, and with the control unit having been moved toward the back side with reference to the display unit;

FIG. 12 is a side view illustrating the usage state of the display device according to the second embodiment of the present invention, with the cross section of a portion of the display device being depicted, and with the control unit having been turned (inclined) in comparison with the state in FIG. 11;

FIG. 13 is a plan view illustrating a control unit of a display device according to a third embodiment of the present invention;

FIG. 14 is a plan view illustrating the usage state of the display device according to the third embodiment of the present invention;

FIG. 15 is a side view illustrating the usage state of the display device according to the third embodiment of the present invention, with the cross section of a portion of the display device being depicted; and

FIG. 16 is an explanatory view illustrating the configuration of a conventional display device.

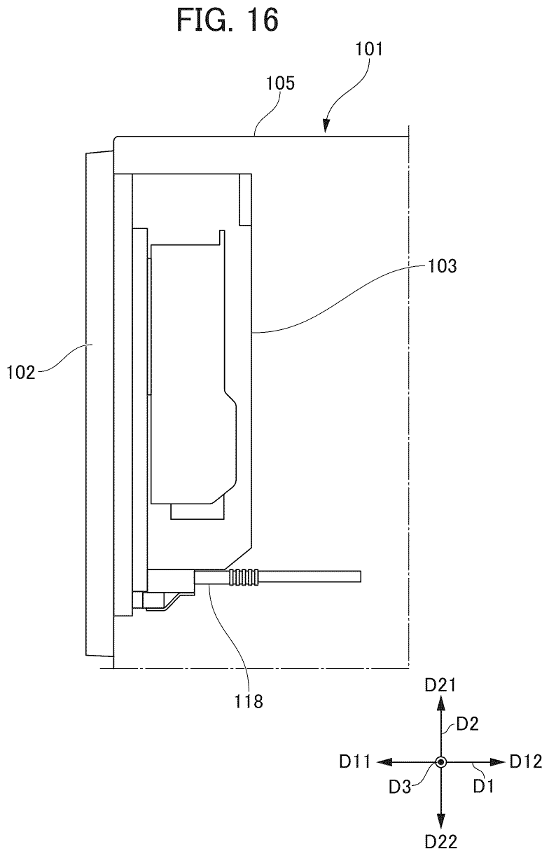

### PREFERRED MODE FOR CARRYING OUT THE INVENTION

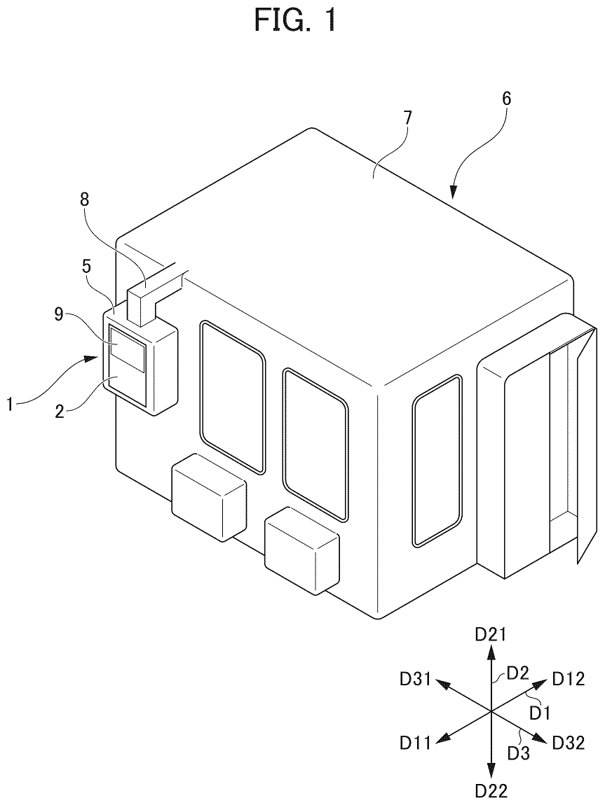

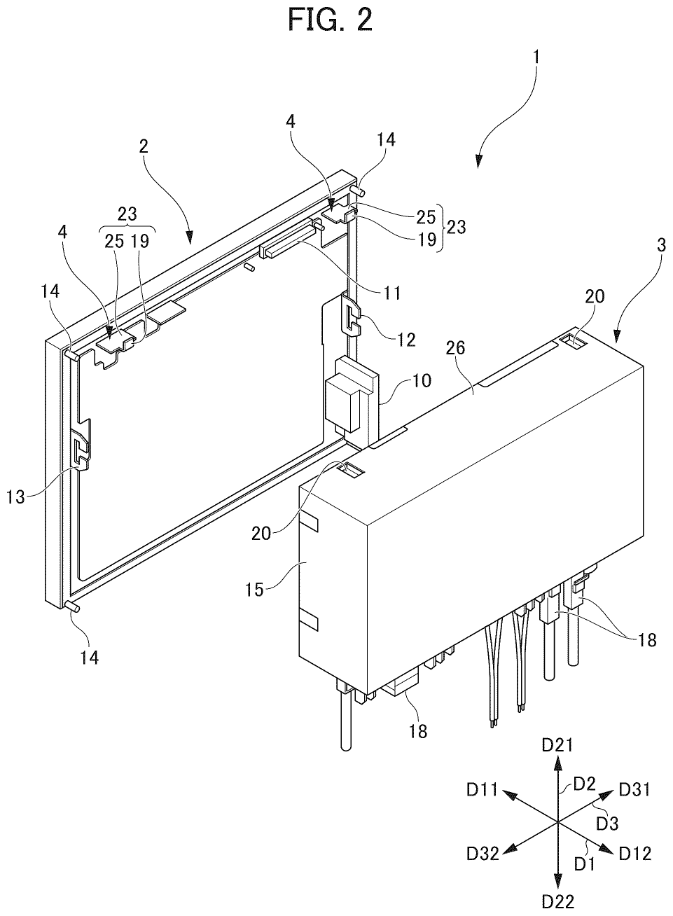

The following describes a display device according to one aspect of the present disclosure with reference to the drawings. As depicted in FIGS. 1 and 2, a display device 1 according to the first embodiment includes: a display unit 2; a control unit 3 that controls the display unit 2; connection parts 4 that connect the display unit 2 and the control unit 3; and a housing 5 in which the display unit 2 and the control unit 3 are provided in a state of being connected to each other. For example, the display device 1 is provided on a machine tool 6 for machining an object. The display device 1 is suspended from a body part 7 of the machine tool 6 via a support section 8. The display device 1 may also be attached to an outer surface of the body part 7 of the machine tool 6.

The display unit 2 includes a display screen 9 of a liquid crystal type. Note that the display screen 9 is not limited to a liquid crystal type, and may be of another type. For example, the control unit 3 is a numerical control unit for a machine tool 6 based on a computer numerical control (CNC).

In the following, a front-rear direction D1, an up-down direction D2, and a left-right direction D3 are defined with the display screen 9 of the display unit 2 being viewed from the front. To be specific, the direction from the control unit 3 toward the display unit 2 (direction from the lower-right area toward the upper-left area in FIG. 2) is defined as a frontward direction D11 or a front side D11, the direction opposite to the frontward direction or the front side is defined as a rearward direction D12, a rear side D12, or a back side D12, and these directions are collectively defined as a front-rear direction D1. An upward direction D21 or an upside D21 (upward direction in FIG. 2) and a downward direction D22 or a downside D22, which is opposite to the upward direction or the upside, are collectively defined as an up-down direction D2. A leftward direction D31 or a left side D31 (direction from the lower-left area toward the upper-right area in FIG. 2) and a rightward direction D32 or a right side D32, which is opposite to the leftward direction or the left side, are collectively defined as a left-right direction D3. Some of the drawings depict arrows indicating these directions.

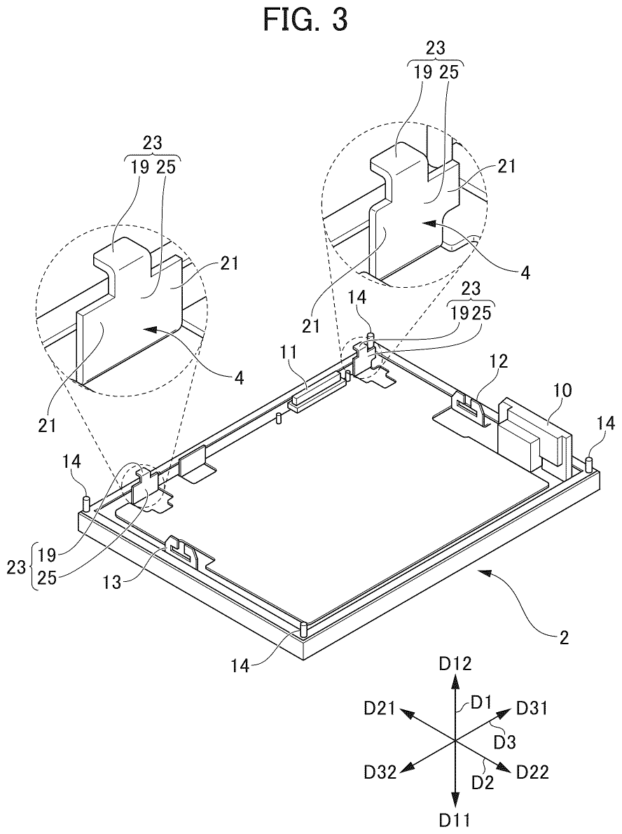

As depicted in FIG. 1, the display screen 9 is disposed on the front surface (front side D11) of the display unit 2. As depicted in FIGS. 2 and 3, a user interface unit 10 connected to an external device (not shown) is provided on the back surface (rear side D12) of the display unit 2. The user interface unit 10 is detachably provided on a lower edge portion (downside D22), on the left side D31, of the back surface of the display unit 2. A connector 11 is provided on the back surface of the display unit 2. The connector 11 is provided on an upper edge portion (upside D21), on the left side D31, of the back surface of the display unit 2. A pair of engagement sections 12 and 13 are arranged in the left-right direction D3 on the back surface of the display unit 2. The first engagement section 12, from among the pair of engagement sections 12 and 13, is provided on a left edge portion (left side D31) of the back surface of the display unit 2, and the second engagement section 13 is provided on a right edge portion (right side D32) of the back surface of the display unit 2. Insertion sections 14 are provided at four corners of the back surface of the display unit 2. Each insertion section 14 is rod-shaped and provided on the back surface of the display unit 2 and projects in the rearward direction D12.

As depicted in FIGS. 2, 4, and 5, the control unit 3 includes an accommodation body 15 having a box shape. A controller (not shown) for controlling the display unit 2 is accommodated in the accommodation body 15. A through-hole 17 penetrating in the front-rear direction D1 is provided in a front plate 16 of the accommodation body 15. A connector (not shown) that is connected to the connector 11 of the display unit 2 is provided in the accommodation body 15 at a position corresponding to the through-hole 17. The accommodation body 15 is provided with a pair of engagement reception sections (not shown). One engagement reception section, from among the pair of engagement reception sections, is provided at a left side plate of the accommodation body 15, and the other engagement reception section is provided at a right side plate thereof. Functions of the pair of engagement reception sections are described hereinafter.

The control unit 3 can have connected thereto a plurality of external connectors 18 for connecting to elements external to the control unit 3. Each external connector 18 is connected, in an insertable/removable manner, to a connector (not shown) provided on a lower portion of the control unit 3. In the illustrated example, the insertion/removal direction of the external connectors 18 is the up-down direction D2, which is orthogonal to the thickness direction (typically, front-rear direction D1) of the control unit 3.

The connection parts 4 each include a bend section 19, a first engagement reception section 20, first abutment sections 21, and second abutment sections 22. As depicted in FIGS. 2 to 5, the bend section 19 and the first abutment sections 21 are disposed on the back side D12 of the display unit 2, and the first engagement reception sections 20 and the second abutment section 22 are disposed on the foreside (front side D11) of the control unit 3. The bend section 19 and the first abutment sections 21 of each of the connection parts 4 in the first embodiment integrally form a first connection section 23. A pair of first connection sections 23 are arranged in the left-right direction D3. The first engagement reception section 20, the second abutment sections 22, and a through-hole 27 (described hereinafter) form a second connection section 24. A pair of second connection sections 24 are arranged in the left-right direction D3. The first connection section 23 and the second connection section 24 are opposed to each other in the front-rear direction D1 on each of the left side D31 and the right side D32, thereby forming a set of connection parts.

The pair of first connection sections 23 are formed integrally with the display unit 2. One first connection section 23, from among the pair of first connection sections 23, is provided on an upper edge portion of the back surface of the display unit 2 on the left side D31, and the other first connection section 23 is provided on an upper edge portion of the back surface of the display unit 2 on the right side D32.

Each of the first connection sections 23 includes a plate piece section 25 that is plate-shaped and connected to the back surface of the display unit 2, and a bend section 19 that bends upward (upward direction D21). The plate piece section 25 is connected to an upper edge portion of the back surface of the display unit 2 and extends toward the rear side D12. The plate surface of the plate piece section 25 faces in the up-down direction D2. The bend section 19 is provided on a rear edge portion (rear side D12) of the plate piece section 25. The bend section 19 is connected to the plate piece section 25 so as to bend in the upward direction D21. In the first embodiment, the bend section 19 is provided integrally with the plate piece section 25. Meanwhile, the bend section and the plate piece section may be separate bodies. With respect to the left-right direction D3, as depicted in FIGS. 2 and 3, the bend section 19 is provided on a substantially central portion of the plate piece section 25 in the left-right direction D3. Thus, the plate piece section 25 includes portions that extend outward of the bend section 19 in the left-right direction D3. The portions that extend outward constitute the first abutment sections 21. That is, both edge portions of the plate piece section 25 in the left-right direction D3 are the first abutment sections 21.

The pair of second connection sections 24 are formed integrally with the control unit 3. One second connection section 24, from among the pair of second connection sections 24, is provided in an upper edge portion of the control unit 3 on the left side D31, and the other second connection section 24 is provided in an upper edge portion of the control unit 3 on the right side D32.

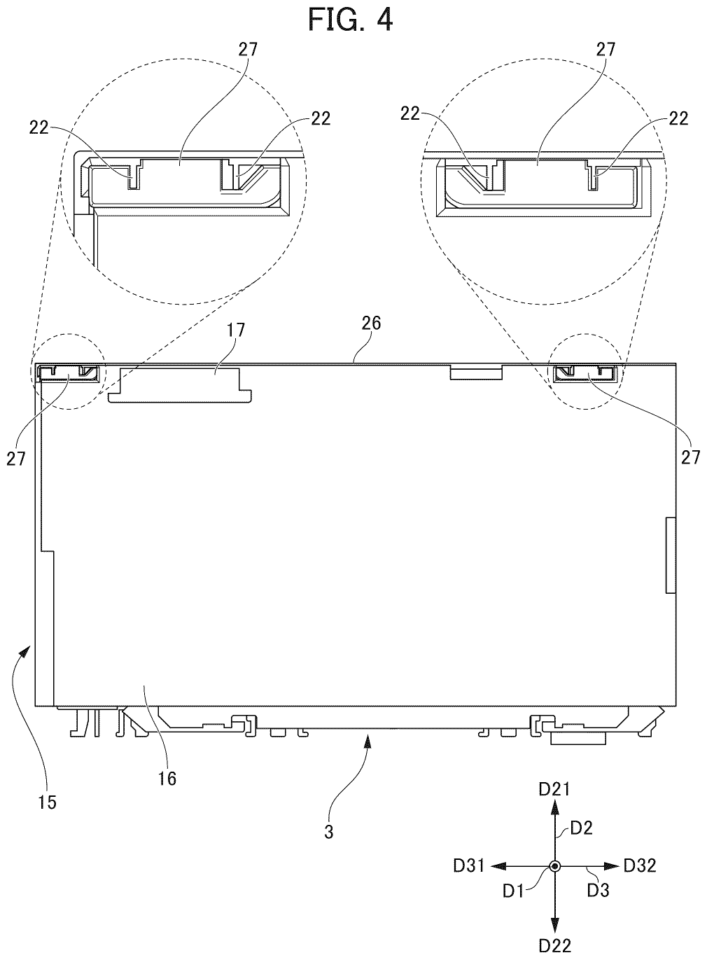

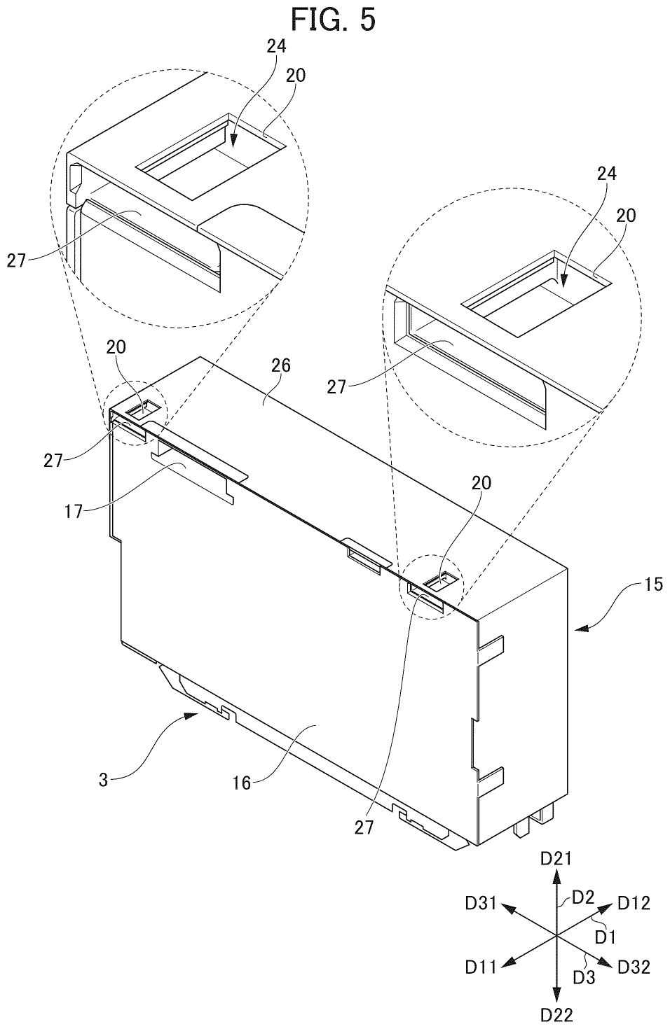

Each of the second connection sections 24 includes a first engagement reception section 20 that is engaged by a bend section 19, and second abutment sections 22 that abut first abutment sections 21. The first engagement reception section 20 includes a through-hole provided so as to penetrate an upper plate 26 of the accommodation body 15 of the control unit 3 in the up-down direction D2. The first engagement reception section 20 is shaped like a quadrangle when viewed in a plan view. The second abutment sections 22 are a pair of plate-shaped sections provided on the inner surface side of the upper plate 26 of the accommodation body 15 of the control unit 3. The pair of second abutment sections 22 extend downward from the upper plate 26. Each second abutment section 22 of the pair of plate-shaped second abutment sections 22 extends in the front-rear direction. Thus, the abutment surface of each of the second abutment sections 22 faces in the up-down direction D2. The pair of second abutment sections 22 are disposed so as to have the first engagement reception section 20 therebetween. As depicted in FIGS. 4 and 5, a through-hole 27 is provided, on the front side D11 of each of the first engagement reception sections 20, in the front plate 16 of the accommodation body 15 of the control unit 3. The through-hole 27 penetrates the front plate 16 in the front-rear direction D1 and extends in the front-rear direction D1.

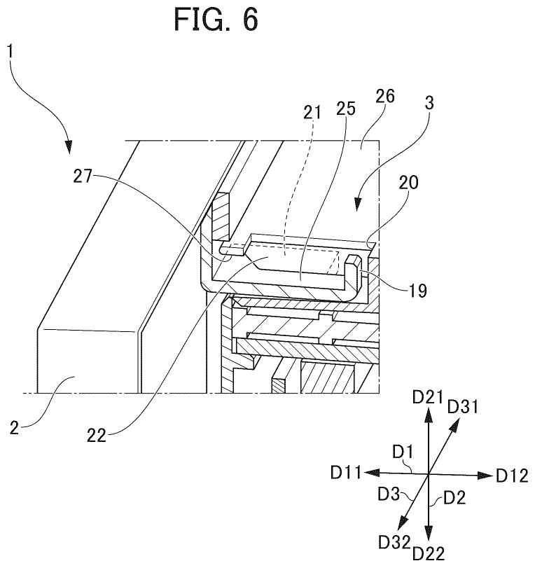

The display device 1 has such a configuration. Accordingly, passing the first connection parts 23 of the display unit 2 through the through-holes 27 of the control unit 3 by causing the control unit 3 to approach the display unit 2 linearly in the frontward direction D11 connects, as depicted in FIG. 6, the display unit 2 and the control unit 3 at the upper portions thereof. Under this condition, the pair of engagement sections 12 and 13 engage the abovementioned pair of engagement reception sections (not shown) of the accommodation body 15. The connector 11 of the display unit 2 is inserted into the inside of the accommodation body 15 through the through-hole 17. When the display unit 2 and the control unit 3 have been connected, each pair of second abutment sections 22 abut the left and right first abutment sections 21 of a plate piece section 25. Specifically, the second abutment section 22 on the left side, from among the pair of second abutment sections 22, abuts the left first abutment section 21 of the plate piece section 25, and the second abutment section 22 on the right side abuts the right first abutment section 21 of the plate piece section 25.

As described above, each pair of second abutment sections 22 are disposed so as to have a first engagement reception section 20 therebetween. Thus, while the display unit 2 and the control unit 3 are connected, the pair of second abutment sections 22 do not contact a bend section 19. Accordingly, the pair of second abutment sections 22 are disposed, on the control-unit-3 side, at a position that does not cause interference between the pair of second abutment sections 22 and the bend section 19.

When the control unit 3 has been fixed to the back side D12 of the display unit 2 in the manner described above, the insertion/removal direction of the external connectors 18 is the direction in which the back surface of the display unit 2 extends. Note that, according to the known art, the insertion/removal direction of the external connectors 18 would be the thickness direction of the display unit 2, as described above. In the illustrated example of the present invention, by contrast, the insertion/removal direction of the external connectors 18, which are disposed on the lower edge portion of the control unit 3, is the up-down direction D2.

When the control unit 3 has been fixed to the display unit 2, the control unit 3 can be removed from the display unit 2 by moving the control unit 3 in the rearward direction D12. Moving the control unit 3 in the rearward direction D12 disconnects the first connection sections 23 from the control unit 3, thereby releasing the connection between the display unit 2 and the control unit 3. Thus, causing the control unit 3 to be spaced apart from the back side of the display unit 2 linearly in the rearward direction D12 allows, by way of the connection parts 4, the control unit 3 to detach from the display unit 2. As described above, the connection parts 4 can connect the display unit 2 and the control unit 3. Thus, the connection parts 4 can detachably connect the back side D12 of the display unit 2 to the control unit 3.

As depicted in FIG. 1, the housing 5 has a rectangular box shape. The display unit 2 is attached to the front plate of the housing 5. When attaching the display unit 2 to the housing 5, the insertion sections 14 provided on the display unit 2 are inserted into an insertion hole (not shown) provided in the front plate of the housing 5. Under this condition, the display unit 2 is fixed to the housing 5 with, for example, a screw. When the display unit 2 has been fixed to the housing 5, the control unit 3 fixed to the display unit 2 is accommodated in the housing 5 through an opening section (not shown) provided in the front plate of the housing 5. In this way, the display unit 2 and the control unit 3 are attached to the housing 5.

The housing 5 is suspended from the body part 7 of the machine tool 6 via the support section 8. The housing 5 is provided on the support section 8 so as to be capable of rotating on a rotation axis in the up-down direction D2. Hence, the control unit 3 is exposed by rotating the display device 1 with reference to the state in FIG. 1 and then removing a rear plate from the housing 5. Accordingly, tasks for the control unit 3 can be easily carried out.

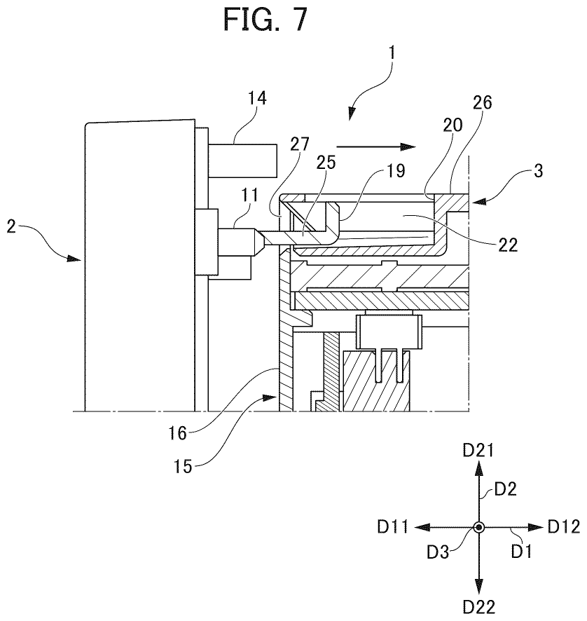

Next, descriptions are given of operations on the display device 1 performed when carrying out a task for the control unit 3. When carrying out a task for the control unit 3, the control unit 3 provided in the housing 5 is exposed as described above. Then, the control unit 3 is moved, as depicted in FIG. 7, in the rearward direction D12 with reference to the state in which the control unit 3 is fixed to the display unit 2. The control unit 3 is moved in the rearward direction D12 until the abutment between the first abutment sections 21 and the second abutment sections 22 is released. When the abutment between the first abutment sections 21 and the second abutment sections 22 has been released, the bend sections 19 are located in the control unit 3.

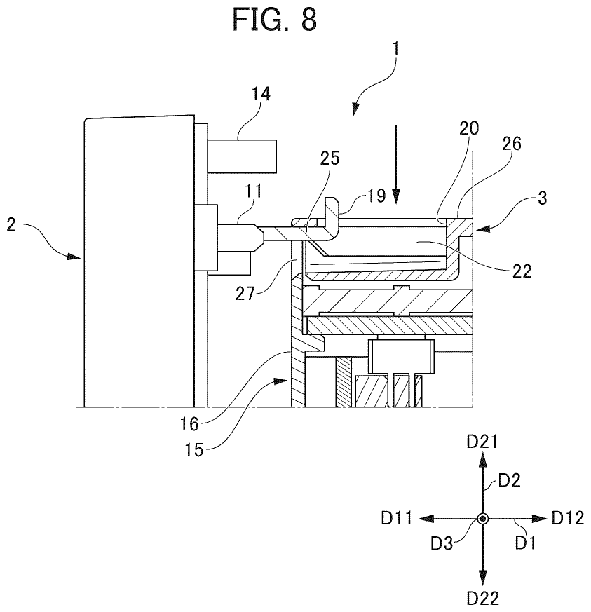

Thereafter, as depicted in FIG. 8, the control unit 3 is moved in the downward direction D22 with reference to the display unit 2. As a result, the bend sections 19 are engaged by the first engagement reception sections 20. Specifically, the leading end portions of the bend sections 19 penetrate the first engagement reception sections 20, and the base end portions of the bend sections 19 contact the upper plate 26. Accordingly, during the process of causing the control unit 3 to be spaced apart from the back side of the display unit 2 linearly in the rearward direction D12, moving the control unit 3 in a direction (downward direction D22 with reference to this example) different from the linearly spacing direction allows the connection parts 4 to form the engagement between the bend sections 19 and the first engagement reception sections 20.

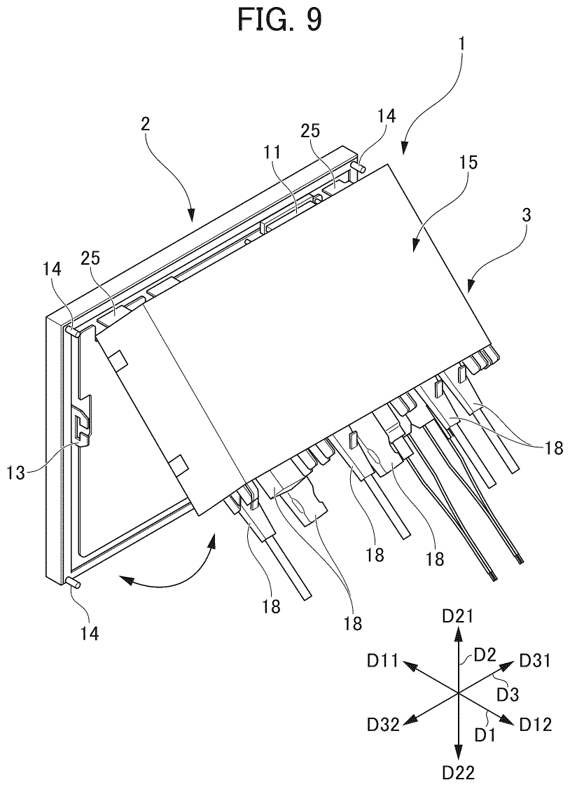

In the first embodiment, when the bend sections 19 have been engaged by the first engagement reception sections 20, the control unit 3, as depicted in FIG. 9, can be turned, with engagement portions of the bend sections 19 and the first engagement reception sections 20 serving as a fulcrum, and with the left-right direction D3 being defined as a turn axis (turn center). Thus, the connection parts 4 connect the control unit 3 and the display unit 2 such that the control unit 3 can be turned so as to be spaced apart from or approach the back side D12 of the display unit 2. Since the control unit 3 can be turned with respect to the display unit 2, the lower edge portion of the control unit 3 can be spaced apart from or approach the display unit 2. Accordingly, the connection parts 4 connect the control unit 3 and the display unit 2 such that the external connectors 18 can be rotated with the external connectors 18 being disposed on the outside in the radial direction (side distant from the turn axis).

In the display device 1 according to the first embodiment, the insertion/removal direction of the external connectors 18 provided on the control unit 3 is the direction in which the back surface of the display unit 2 extends. Thus, the display device 1 can be made compact. In the display device 1 according to the first embodiment, the control unit 3 can be turned with respect to the display unit 2. Hence, when inserting/removing an external connector 18 into/from the back side of the control unit 3, the control unit 3 can be turned upward with respect to the display unit 2. In this way, the abovementioned connector (not shown) that is a connection part via which the external connector 18 is connected to the control unit 3 can be easily visually checked, so that the external connector 18 can be easily inserted/removed into/from the control unit 3.

In the display device 1 according to the first embodiment, the connection parts 4 each include a bend section 19, a first engagement reception section 20, first abutment sections 21, and second abutment sections 22. Thus, the display device 1 according to the first embodiment allows the connection parts 4 to have a simple configuration.

With respect to the display device 1 according to the first embodiment, during the process of causing the control unit 3 to be spaced apart from the back side of the display unit 2 linearly in the rearward direction D12, moving the control unit 3 in a direction (downward direction D22) different from the linearly spacing direction (rearward direction D12) allows the bend sections 19 and the first engagement reception sections 20 to be engaged by each other. Thus, the display device 1 according to the first embodiment can easily cause the bend sections 19 to be engaged by the first engagement reception sections 20.

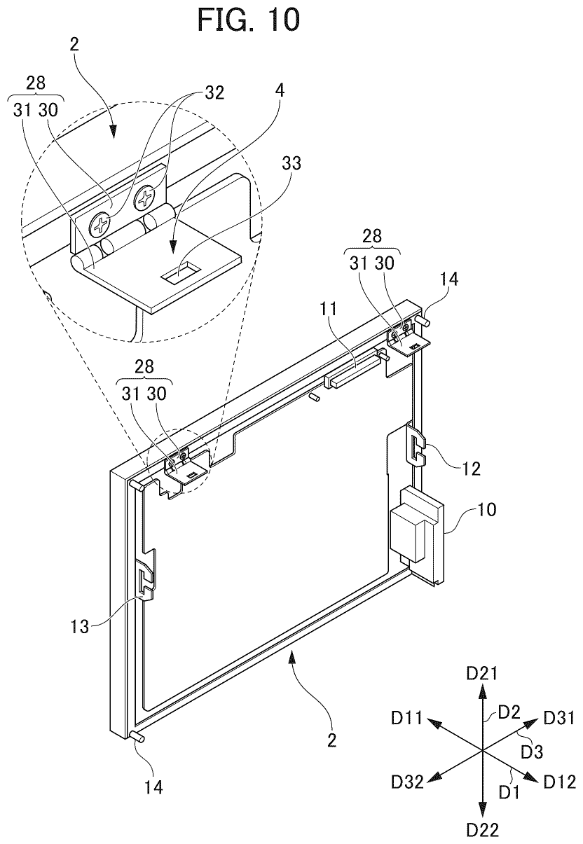

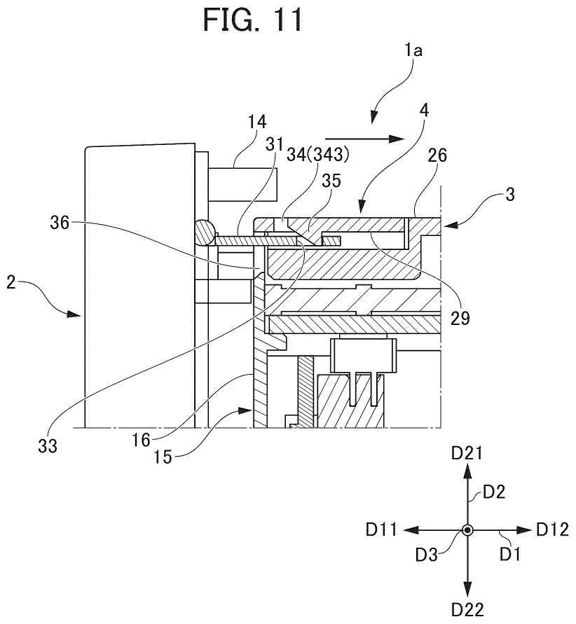

The following describes a second embodiment of the display device of the present invention with reference to FIGS. 10 and 11. Components with an identical reference mark with ones in the first embodiment have similar functions, and descriptions thereof may be omitted hereinafter. A display device 1a according to the second embodiment differs from the first embodiment in terms of the configuration of connection parts 4. In particular, the connection parts 4 each include: a pair of hinge sections 28 disposed on the back side D12 of the display unit 2; and a pair of slide engagement sections 29 disposed on the front side D11 of the control unit 3.

The pair of hinge sections 28 are formed integrally with the display unit 2. One hinge section 28, from among the pair of hinge sections 28, is provided on an upper edge portion of the back surface of the display unit 2 on the left side D31, and the other hinge section 28 is provided on an upper edge portion of the back surface of the display unit 2 on the right side D32.

Each of the hinge sections 28 includes a plate-shaped fixed piece 30 and a plate-shaped movable piece 31. The fixed piece 30 and the movable piece 31 are turnably coupled to each other. The turn axis extends in the left-right direction D3. As depicted in FIG. 10, the fixed piece 30 is fixed to the back surface of the display unit 2 with, for example, screws 32, thereby fixing the hinge section 28 to the back surface of the display unit 2. When the hinge section 28 has been fixed to the display unit 2, the movable piece 31 extends substantially horizontally from the display unit 2. The hinge section 28 in the second embodiment is configured such that the movable piece 31 does not turn downward with reference to the state in which the movable piece 31 horizontally extends. The movable piece 31 includes a second engagement reception section 33. The second engagement reception section 33 is a hole provided so as to penetrate the movable piece 31.

The pair of slide engagement sections 29 are formed integrally with the control unit 3. One slide engagement section 29, from among the pair of slide engagement sections 29, is provided in an upper edge portion of the control unit 3 on the left side D31, and the other slide engagement section 29 is provided in an upper edge portion of the control unit 3 on the right side D32.

As described hereinafter, each of the slide engagement sections 29 can slide along a movable piece 31. The slide engagement section 29 is provided in the upper plate 26 by providing a continuous groove 34 in the upper plate 26 (by forming a recess in the upper plate 26). The groove 34 includes a first groove (not shown), a second groove (not shown), and a third groove 343. The first and second grooves are disposed so as to be spaced apart from each other in the left-right direction D3. The first and second grooves are provided so as to penetrate the upper plate 26 in the up-down direction D2. The first and second grooves extend in the front-rear direction D1. The third groove 343 is provided so as to penetrate the upper plate 26 in the up-down direction D2. The third groove 343 connects the front end portion of the first groove and the front end portion of the second groove (end portions on the front side D11). The slide engagement section 29 is provided in the upper plate 26 by providing the first groove, the second groove, and the third groove 343. The slide engagement section 29, which is plate-shaped, can be elastically deformed upward and downward, with the rear end portion (end portion on the rear side D12) thereof as a fulcrum. The slide engagement section 29 includes a projection section 35 engaged by the second engagement reception section 33. The projection section 35 is provided on the inner surface side of the slide engagement section 29. The projection section 35 projects from the slide engagement section 29 in the downward direction D22. The front surface of the projection section 35 is an inclined surface that extends in the rearward direction D12 while being inclined in the downward direction D22.

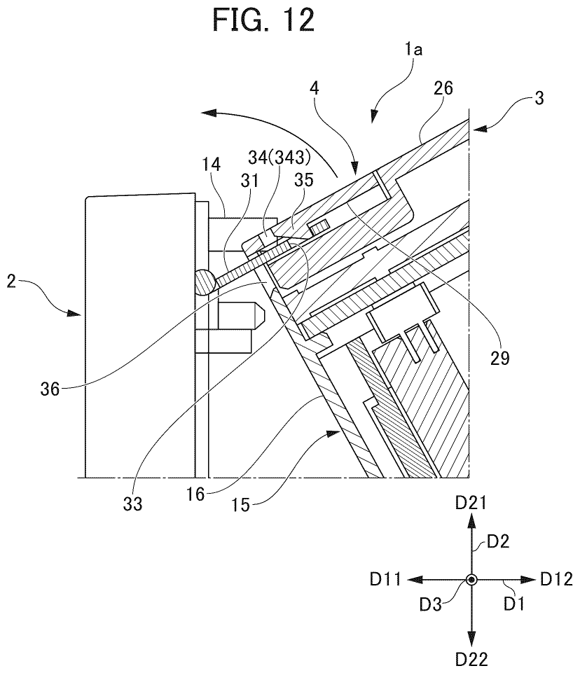

As depicted in FIGS. 11 and 12, a through-hole 36 is provided, on the front side D11 of each of the slide engagement sections 29, in the front plate 16 of the accommodation body 15 of the control unit 3. The through-hole 36 is a hole penetrating the front plate 16 in the front-rear direction D1.

The display device la according to the second embodiment has such a configuration. Thus, passing the movable pieces 31 of the hinge sections 28 through the through-holes 36 of the control unit 3 by bringing the control unit 3 to close the display unit 2 linearly in the frontward direction D11 connects the display unit 2 and the control unit 3. Bringing the control unit 3 closer to the display unit 2 while passing the movable pieces 31 through the through-holes 36 brings the rear edge portions of the movable pieces 31 into contact with the front surfaces of the projection sections 35. Further bringing the control unit 3 closer to the display unit 2 brings the projection sections 35 into contact with the upper surfaces of the movable pieces 31, with the slide engagement sections 29 being elastically deformed upward. Still further bringing the control unit 3 closer to the display unit 2 causes the slide engagement sections 29 to slide along the movable pieces 31, with the projection sections 35 being in contact with the upper surfaces of the movable pieces 31.

When the control unit 3 has been fixed to the display unit 2 in such a manner, the control unit 3 can be removed from the display unit 2 by moving the control unit 3 in the rearward direction D12. Moving the control unit 3 in the rearward direction D12 disconnects the movable pieces 31 from the control unit 3, thereby releasing the connection between the display unit 2 and the control unit 3.

Next, descriptions are given of operations on the display device la performed when carrying out a task for the control unit 3. When carrying out a task for the control unit 3, the control unit 3 provided in the housing 5 is exposed as described above. Then, the control unit 3 is moved, as depicted in FIG. 11, in the rearward direction D12 with reference to the state in which the control unit 3 is fixed to the display unit 2. Moving the control unit 3 in the rearward direction D12 causes the slide engagement sections 29 to slide along the movable pieces 31, with the projection sections 35 being in contact with the upper surfaces of the movable pieces 31. Upon the projection sections 35 arriving at the second engagement reception sections 33 of the movable pieces 31, the projection sections 35 are deformed downward and inserted into the second engagement reception sections 33. As a result, the projection sections 35 of the slide engagement sections 29 are engaged by the second engagement reception sections 33. In the second embodiment, when the slide engagement sections 29 have been engaged by the second engagement reception sections 33, the control unit 3, as depicted in FIG. 12, can be turned upward or downward by the hinge sections 28.

Hence, when inserting/removing an external connector 18 into/from the back side D12 of the control unit 3, the control unit 3 can be turned upward with respect to the display unit 2. In this way, the abovementioned connector (not shown) that is a connection part via which the external connector 18 is connected to the control unit 3 can be easily visually checked, so that the external connector 18 can be easily inserted/removed into/from the control unit 3.

In the display device la according to the second embodiment, the connection parts 4 each include: a hinge section 28 disposed on the display-unit-2 side; and a slide engagement section 29 disposed on the control-unit-3 side. Thus, the display device la according to the second embodiment allows the connection parts 4 to have a simple configuration. Owing to the display device la having such a configuration, the slide engagement sections 29 and the second engagement reception sections 33 can be engaged by each other by simply moving the control unit 3 in the rearward direction D12 with respect to the display unit 2. In accordance with the display device la according to the second embodiment, accordingly, operations on the display device la can be easily performed when carrying out a task for the control unit 3.

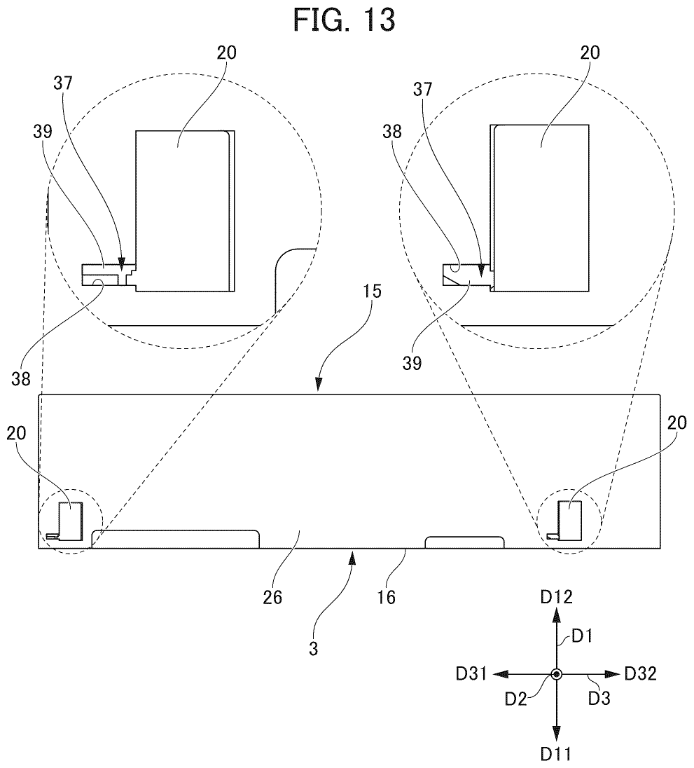

The following describes a third embodiment of the display device of the present invention with reference to FIGS. 13, 14, and 15. Components with an identical reference mark with ones in the first embodiment have similar functions, and descriptions thereof may be omitted hereinafter. A display device 1b according to the third embodiment can keep the control unit 3 inclined with respect to the display unit 2. In particular, connection parts 4 each include an engagement retaining section 37 for retaining the engagement between a bend section 19 and a first engagement reception section 20.

The engagement retaining sections 37 each have a groove 38 provided in the upper plate 26 of the accommodation body 15 of the control unit 3. The groove 38 penetrates the upper plate 26 in the up-down direction D2. The groove 38 is provided in the upper plate 26 so as to be continuous with the front edge portion of the first engagement reception section 20. The groove 38 extends from the first engagement reception section 20 toward one side in the left-right direction D3. Although the groove 38, in the illustrated example, extends from the first engagement reception section 20 in the leftward direction D31, the same may extend in the rightward direction D32.

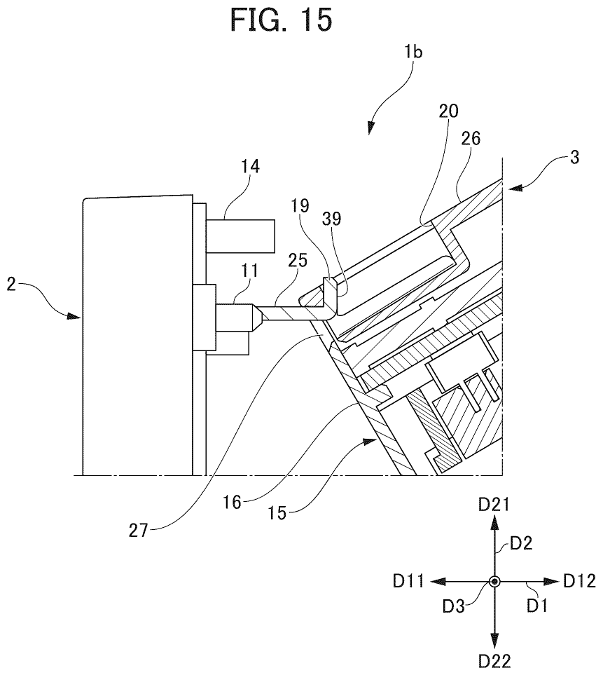

As depicted in FIGS. 13 and 15, inclined surfaces 39 are each provided inside the accommodation body 15. When the control unit 3 has been fixed to the display unit 2, the inclined surface 39 extends in the frontward direction D11 while being inclined in the downward direction D22. The inclined surface 39 is positioned on the downside D22 with reference to the groove 38.

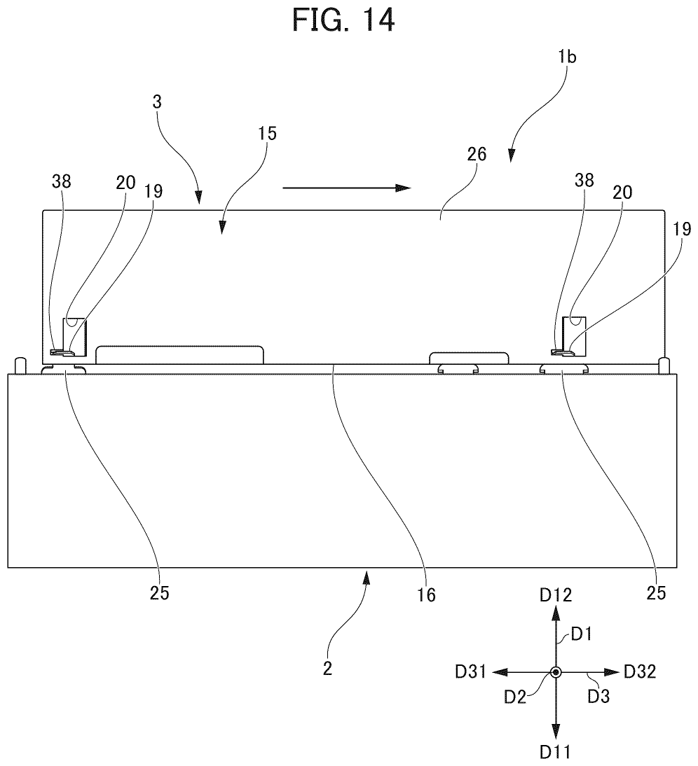

The display device 1b according to the third embodiment has such a configuration. Thus, the bend sections 19 are moved into the grooves 38 by causing the control unit 3 to slide toward the other side in the left-right direction D3 with the control unit 3 turned upward as in the first embodiment. In the illustrated example, the grooves 38 extend in the leftward direction D31, so the control unit 3 is caused to slide in the rightward direction D32. Moving the bend sections 19 into the grooves 38 brings, as depicted in FIGS. 14 and 15, the bend sections 19 into contact with the inclined surfaces 39. In this way, the control unit 3 can be kept inclined with respect to the display unit 2 with the bend sections 19 and the first engagement reception sections 20 being engaged by each other. Accordingly, moving the control unit 3 in a direction different from the movement direction for forming the engagement between the bend sections 19 and the first engagement reception sections 20 allows the engagement retaining sections 37 to retain the engagement between the bend sections 19 and the first engagement reception sections 20.

The display device 1b according to the third embodiment can keep the control unit 3 inclined with respect to the display unit 2. Thus, when inserting or removing an external connector 18, an operator does not need to support the control unit 3 of the display device 1b according to the third embodiment with the control unit 3 being inclined. Accordingly, external connectors 18 can be inserted or removed more easily.

The present invention is not limited to the embodiments, and encompasses variations and improvements with which objects of the present invention can be achieved.

For example, the direction in which the turn axis (turn center) of the control unit 3 extends is not limited to the left-right direction D3 but may be the up-down direction D2. The linearly spacing direction is not limited to the front-rear direction D1 (rearward direction D12). The direction (movement direction for forming the engagement between the bend sections 19 and the first engagement reception sections 20) different from the linearly spacing direction is not limited to the downward direction D22 but may be a diagonally downward direction. The direction different from the movement direction for forming the engagement between the bend sections 19 and the first engagement reception sections 20 is not limited to the left-right direction D3.

In the second embodiment, the angle formed between the fixed piece and the movable piece of each hinge section may be set to a predetermined angle. Typically, the hinge section may be a torque hinge.

In the second embodiment, a connector connection part between the display unit 2 and the control unit 3 may be a flexible printed circuit (FPC).

### EXPLANATION OF REFERENCE NUMERALS

1: Display device
2: Display unit
3: Control unit
4: Connection part
18: External connector
19: Bend section
20: First engagement reception section
21: First abutment section
22: Second abutment section
28: Hinge section
29: Slide engagement section
30: Fixed piece
31: Movable piece
33: Second engagement reception section
37: Engagement retaining section

1. A display device comprising:
a display unit;
a control unit that controls the display unit; and
a connection part that connects the display unit and the control unit, wherein the connection part is capable of detachably connecting a back side of the display unit to the control unit,
the control unit is capable of having connected thereto an external connector for connecting to an element external to the control unit,
when the control unit has been fixed to the back side of the display unit, an insertion/removal direction of the external connector is a direction in which a back surface of the display unit extends, and
the connection part establishes a connection such that the control unit is capable of being turned so as to be spaced apart from or approach the back side of the display unit and such that the external connector is capable of being rotated with the external connector being disposed on an outside in a radial direction.

2. The display device according to claim 1, wherein
the connection part includes a bend section that is disposed on the back side of the display unit and bends upward, and a first engagement reception section that is disposed on a control-unit side and is engaged by the bend section.

3. The display device according to claim 2, wherein
causing the control unit to be spaced apart linearly from the back side of the display unit allows, by way of the connection part, the control unit to detach from the display unit, and
during a process of causing the control unit to be spaced apart linearly from the back side of the display unit, moving the control unit in a direction different from a linearly spacing direction allows the connection part to form engagement between the bend section and the first engagement reception section.

4. The display device according to claim 2, wherein
the connection part further includes an engagement retaining section that retains engagement between the bend section and the first engagement reception section.

5. The display device according to claim 4, wherein
moving the control unit in a direction different from a movement direction for forming engagement between the bend section and the first engagement reception section causes the engagement retaining section to retain the engagement between the bend section and the first engagement reception section.

6. The display device according to claim 2, wherein
the connection part includes a first abutment section that is disposed on the back side of the display unit, and a second abutment section that abuts the first abutment section and that is disposed on the control-unit side at a position that does not cause interference between the second abutment section and the bend section.

7. The display device according to claim 1, wherein
the connection part includes a hinge section that is disposed on the back side of the display unit and has a fixed piece and a movable piece, and a slide engagement section that is disposed on a control-unit side and is capable of sliding along the movable piece,
the movable piece of the hinge section includes a second engagement reception section, and
the slide engagement section includes a projection section that projects downward and is engaged by the second engagement reception section.

8. The display device according to claim 7, wherein
an angle formed between the fixed piece and the movable piece of the hinge section can be set to a predetermined angle.
